(19) United States
(12) Patent Application Publication
(10) Pub. No.: US 2010/0029086 A1
(43) Pub. Date: Feb. 4, 2010

(54) METHOD FOR MANUFACTURING SEMICONDUCTOR DEVICE AND STORAGE MEDIUM

(75) Inventors: Hidenori Miyoshi, Nirasaki-shi (JP); Eiichi Nishimura, Nirasaki-shi (JP); Kazuhiro Kubota, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTON LIMITED, Tokyo (JP)

(21) Appl. No.: 12/555,283

(22) Filed: Sep. 8, 2009

Related U.S. Application Data
(63) Continuation of application No. PCT/JP08/53858, filed on Mar. 4, 2008.

(30) Foreign Application Priority Data
Mar. 8, 2007 (JP) 2007-059112

(51) Int. Cl. H01L 21/306

(52) U.S. Cl. 438/737; 257/E21.219

(57) ABSTRACT

A semiconductor device having high reliability is provided by reducing fluorine remaining in a metal forming the semiconductor device. Specifically disclosed is a method for manufacturing a semiconductor device including a fluoride removal step for removing a metal fluoride produced on a metal forming an electrode or wiring of a semiconductor device which is formed on a substrate to be processed. This method for manufacturing a semiconductor device is characterized in that the metal fluoride is removed by supplying formic acid in a gaseous state to the substrate to be processed in the fluoride removal step.

This application is a Continuation Application of PCT International Application No. PCT/JP2008/053858 filed on Mar. 4, 2008, which designated the United States.

### FIELD OF THE INVENTION

The present invention relates to a method for manufacturing a semiconductor device which includes a process for removing a metal fluoride.

### BACKGROUND OF THE INVENTION

With the advance in high performance of semiconductor devices, Cu of low resistivity has been widely used as a wiring material of the semiconductor devices. However, Cu is easily oxidized, so that Cu wiring exposed through an interlayer insulating film may be oxidized in a process for manufacturing a Cu multilayer wiring structure by, e.g., a damascene method. Accordingly, a reducing gas such as NH₃, H₂ or the like has been used to remove the oxidized Cu by reduction.

However, in case of using NH₃ or H₂, the process temperature of the Cu reduction process needs to be high. Therefore, the interlayer insulating film which is made of a so-called low-k material and formed around the Cu wiring may be damaged. To that end, it has been suggested to perform reduction of Cu at a low temperature by using a processing gas, e.g., vaporized formic acid or acetic acid (see, e.g., Patent Documents 1 and 2).

Patent Document 1: Japanese Patent No. 3734447

Patent Document 2: Japanese Patent Laid-open Publication No. 2001-271192

However, a surface of a metal such as Cu or the like may be fluoridized as well as oxidized, so that a metal fluoride in addition to a metal oxide may be formed thereon. When an insulating layer (e.g., an SiO₂ film or the like) covering a metal, e.g., Cu or the like, is etched, a gas containing fluorine as a constituent element may be used as an etching gas.

When the corresponding metal is exposed by plasma-etching (dry etching) the insulating layer on the metal by using the etching gas containing fluorine, the surface of the exposed metal is fluoridized by fluorine contained in the etching gas, which may lead to production of a metal fluoride (e.g., CuF or the like).

When fluorine remains on a metal surface for a long period of time as described above, it may cause corrosion of the corresponding metal. Further, if another metal (e.g., a diffusion barrier film or the like) is formed on the corresponding metal in a following process, in a state where fluorine remains on the metal surface, adhesivity between the corresponding metal and another metal may be reduced.

Moreover, the production of the metal fluoride leads to an increase of an electrical resistance on the interface between the metal surface and the diffusion barrier layer or the like, so that electrical characteristics of a semiconductor may not be as good as desired.

Furthermore, the insulating layer (e.g., interlayer insulating layer) formed around the metal layer is corroded due to fluorine, so that the reliability of the semiconductor device may deteriorate. In a recent semiconductor device operating at a high speed, a so-called low-k material (low dielectric constant material) is generally used for the interlayer insulating layer. The low-k material has low resistance to corrosion due to fluorine, and thus may be damaged due to fluorine.

Besides, a recent semiconductor device having a miniaturized contact or wiring structure is greatly affected by the increase of the resistance at the interface with the metal or the corrosion due to fluorine. Hence, the problem of remaining fluorine becomes more severe.

For example, the fluorine on the metal can be removed by using liquid chemical containing water. Since, however, materials (e.g., insulating layers 11B and 21 and the like) forming devices may be damaged by water, it is not preferable in view of considering the entire devices. Especially, in a recent semiconductor device operating at a high speed, a low-k material (low dielectric constant material) having a low relative dielectric constant compared to SiO₂ can be used, instead of a conventional material such as SiO₂ or the like, for the interlayer insulating layer. This low-k material may be easily damaged especially by wet treatment using water or the like.

Besides, when the fluorine on the metal is removed by using water vapor, the materials (insulating layers and the like) forming the devices may be damaged even though the damages can be reduced compared to the case of using water.

### SUMMARY OF THE INVENTION

Therefore, it is a general object of the present invention to provide a new and useful method for manufacturing a semiconductor device which has solved the above-mentioned problems, and a storage medium.

It is a specific object of the present invention to provide a semiconductor device having high reliability by reducing fluorine remaining in a metal forming the semiconductor device.

In accordance with a first aspect of the present invention, there is provided a method for manufacturing a semiconductor device comprising: a fluoride removal step for removing a metal fluoride produced on a metal forming an electrode or wiring of a semiconductor device formed on a substrate to be processed, wherein in the fluoride removal step, the metal fluoride is removed by supplying a formic acid in a gaseous state to the substrate.

Further, the metal may be Cu.

Further, in the fluoride removal step, a metal fluoride produced on the metal exposed through an opening of an insulating layer formed on the metal may be removed.

Further, the method may further comprise an opening forming step for forming the opening, wherein the metal fluoride is produced during the opening forming step.

Further, the opening forming step and the metal fluoride removal step may be carried out successively in a depressurized state.

Further, the insulating layer may contain silicon and carbon as constituent elements.

Further, the insulating layer may contain silicon and carbon as constituent elements, and at least a part of the insulating layer may be porous.

In accordance with a second aspect of the present invention, there is provided a storage medium storing a program for executing, on a computer, a substrate processing method in a substrate processing apparatus including a processing chamber for processing a substrate to be processed, wherein the substrate processing method includes a fluoride removal step for removing a fluoride of a metal by supplying formic acid in a gaseous state to the processing chamber.

Further, the metal may be Cu.

Further, in the fluoride removal step, a metal fluoride produced on the metal exposed through an opening of an insulating layer formed on the metal may be removed.

Further, the substrate processing method may further include an opening forming step for forming the opening, wherein the metal fluoride is produced during the opening forming step.

Further, the opening forming step and the metal fluoride removal step may be carried out successively in a depressurized state.

Further, the insulating layer may contain silicon and carbon as constituent elements.

Further, the insulating layer may contain silicon and carbon as constituent elements, and at least a part of the insulating layer may be porous.

### EFFECTS OF THE INVENTION

In accordance with the present invention, it is possible to provide a semiconductor device having high reliability by reducing fluorine remaining in a metal forming the semiconductor device.

### BRIEF DESCRIPTION OF THE DRAWINGS

FIG. 1A is a first diagram showing an outline of the present invention.

FIG. 1B is a second diagram describing the outline of the present invention.

FIG. 2 illustrates vapor pressure curves of formic acid, acetic acid and water.

FIG. 3 schematically depicts an example of a substrate processing apparatus for executing the present invention.

FIG. 4 illustrates the effects of the present invention.

FIG. 5A presents a F1s XPS spectrum obtained before formic acid treatment.

FIG. 5B represents a F1s XPS spectrum obtained after the formic acid treatment.

FIG. 6A is a first diagram describing a method for manufacturing a semiconductor device.

FIG. 6B is a second diagram showing the method for manufacturing a semiconductor device.

FIG. 6C is a third diagram depicting the method for manufacturing a semiconductor device.

FIG. 6D is a fourth diagram explaining the method for manufacturing a semiconductor device.

FIG. 6E is a fifth diagram illustrating the method for manufacturing a semiconductor device.

FIG. 7 shows another configuration example of the substrate processing apparatus.

### DETAILED DESCRIPTION OF THE EMBODIMENT

A method for manufacturing a semiconductor device in accordance with the present invention includes a fluoride removal step for removing a metal fluoride produced on a metal forming an electrode or wiring of a semiconductor device formed on a substrate to be processed. This method for manufacturing a semiconductor device is characterized in that the metal fluoride is removed by supplying formic acid in a gaseous state to the substrate to be processed in the fluoride removal step.

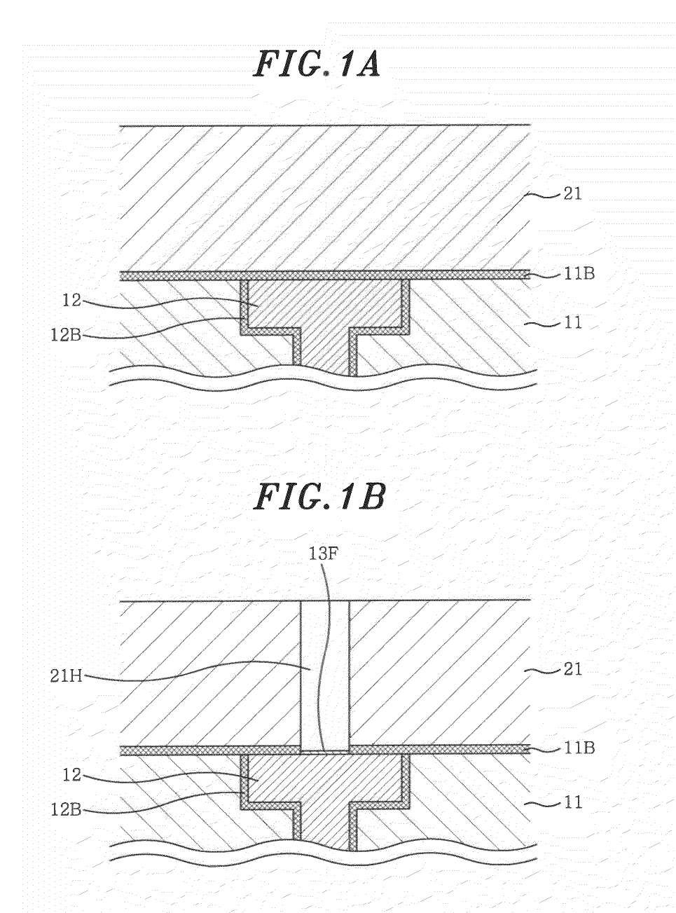

Hereinafter, an outline of the method for manufacturing a semiconductor device will be described with reference to FIGS. 1A and 1B.

First, a process shown in FIG. 1A is one of processes for forming a multilayer wiring structure of a semiconductor device. For example, in a semiconductor device formed on a silicon substrate or the like, it is general to form devices such as an MOS transistor and the like in a lowermost layer of the substrate and then form a multilayer wiring structure connected with the devices on top of the devices.

For example, a wiring portion 12 forming the multilayer wiring structure is formed so as to be buried in an insulating layer (interlayer insulating layer) 11. A diffusion barrier layer 12B for preventing a metal (e.g., Cu) forming the wiring portion 12 from diffusing into the insulating layer 11 is formed between the insulating layer 11 and the wiring portion 12. Further, an insulating layer (cap layer) 11B and an insulating layer (interlayer insulating layer) 21 are stacked on the insulating layer 11 and the wiring portion 12 so as to cover the insulating layer 11 and the wiring portion 12.

The wiring portion 12 is made of a metal, e.g., Cu or the like. The diffusion barrier layer 12B is made of a metal, e.g., Ta, TaN or the like, or a metal nitride. The insulating layers 11 and 21 are made of, e.g., SiO₂. The insulating layer 11B is made of, e.g., SiN.

Here, when a wiring portion stacked on the wring portion 12 is formed by a damascene method, the insulating layers 21 and 11B formed on the wiring portion 12 need to be etched.

Therefore, in a process illustrated in FIG. 1B, the insulating layers 21 and 11B are etched by using a fluorocarbon-based gas containing, e.g., fluorine, as a constituent element (etching process).

For example, in the above-described case, the insulating layer 21 made of SiO₂ is plasma-etched (dry-etched) by using an etching gas containing, e.g., C₄F₈. Further, in the above-described etching process, it is preferable to form, on the insulating layer 21, a mask pattern (not shown) formed by patterning a photoresist layer by using a photolithography technique. Furthermore, the insulating layer 11B made of SiN is plasma-etched by using an etching gas containing, e.g., CHF₃.

As a result, an opening (via hole) 21H which exposes the wiring portion (Cu) 12 through the insulating layers 21 and 11B is formed. Further, it is preferable to etch the insulating layer 21 and the insulating layer 11B while varying gas types or etching conditions as described above.

In addition, if necessary, a multilayer wiring may be formed by processing the opening 21H, forming a recess including a via hole and a trench or the like, and forming a wiring portion (via plug, pattern wiring or the like) so as to bury the corresponding opening.

However, a metal (e.g., Cu) forming the wiring portion 12 tends to easily deteriorate by the surrounding atmosphere of the wiring portion 12. For example, when oxygen exists near the wiring portion 12, a Cu surface is easily oxidized, and an oxide film (cupric oxide CuO) is formed on the Cu surface. Accordingly, there have been suggested various methods for removing the cupric oxide (e.g., Japanese Patent No. 3734447 and Japanese Patent Laid-open Publication No. 2001-271192).

However, the inventors of the present invention have found that the surface of the metal such as Cu or the like is fluoridized by fluorine contained in the etching gas for etching the insulating layer formed on the metal surface and that this may lead to generation of a metal fluoride (e.g., Cu fluoride such as CuF or the like) in addition to formation of an oxide film. For example, when the insulating layer is plasma-etched by using a gas containing fluorine such as C₄F₈ or the like as a constituent element, a Cu fluoride layer (CuF) may be formed due to fluoridation of the Cu surface.

For example, as shown in FIG. 1B, a metal fluoride layer 13F is formed on the surface of the wiring portion 12 exposed through the opening 21H of the insulating layers 11B and 21 formed on top of the wiring portion 12.

When a device is formed by forming a metal (Cu layer, Cu diffusion barrier layer or the like) or an insulating layer on top of the wiring portion in a state where the Cu fluoride layer is formed on the Cu surface, the metal or the insulating layer may be corroded by the remaining fluorine.

For example, if the substrate on which the metal is deposited is exposed to moisture in the air in a state where fluorine remains, the moisture in the air and the fluorine easily bond with each other, thereby generating HF. The HF containing moisture may corrode, e.g., the wiring, the diffusion barrier layer or the insulating layer (interlayer insulating layer), which may lead to damages.

Therefore, in the present invention, upon completion of the process shown in FIG. 1B, there is performed a fluoride removal process for removing the metal fluoride layer 13F by supplying formic acid in a gaseous state to the substrate to be processed on which the metal is deposited.

In a method for manufacturing a semiconductor device which uses the fluoride removal process, the metal fluoride can be effectively removed from the surface of the wiring portion (metal) 12 exposed from the insulating layer 21, so that the corrosion of the corresponding metal can be suppressed. Further, when another metal (e.g., diffusion barrier layer, wiring portion or the like), an insulating layer or the like is formed on the corresponding metal after the fluoride removal process, the adhesivity between the wiring portion 12 and the corresponding metal or the corresponding insulating layer is improved.

By removing the metal fluoride, it is possible to suppress the increase of the electrical resistance due to fluorine present at the interface between the surface of the wiring surface 12 and the metal formed on top of the wiring layer 12. Accordingly, electrical characteristics of a semiconductor device are improved.

Further, it is possible to suppress the corrosion of the insulating layer 11 formed around the wiring portion 12 or the insulating layers 11B and 21 formed on top of the wiring portion 12 due to fluorine. As a consequence, the reliability of a semiconductor device is increased.

For example, in a method for removing fluorine on the metal by water (vapor) (see, e.g., Japanese Patent Laid-open Publication No. 2001-271192), the materials (e.g., the insulating layers 11B and 21 and the like) forming the device may be damaged by water, so that it is not preferable in view of considering the entire device. Especially, in a recent semiconductor device operating at a high speed, a low-k material (low dielectric constant material) having a low relative dielectric constant compared to SiO₂ is used, instead of a conventional material such as SiO₂ or the like, for an interlayer insulating layer. This low-k material may be easily damaged especially by wet treatment using water or the like.

As for the low-k material, there is used a material containing, e.g., carbon in addition to silicon and oxygen, as constituent elements (which may be referred to as a carbon-containing SiO₂ film or the like). Further, if necessary, hydrogen may be added to the low-k material. This low-k layer may be referred to as SiOC, SiCO, SiOCH, SiCO:H or the like. Moreover, as for a material forming the low-k layer, there is known, e.g., HSQ (H-containing polysiloxane), MSQ (methyl-containing polysiloxane) or the like. Besides, the dielectric constant of the interlayer insulating layer can be decreased by using an SiO₂ film or a low-k layer made of a porous material.

The low dielectric layer or the porous layer is easily damaged by, e.g., wet treatment, compared to a conventional SiO₂ film. Accordingly, it is preferable to minimize the processing time (number of cycles) of the wet treatment.

The method for removing a metal fluoride by using formic acid can effectively remove a metal fluoride formed on a metal exposed through the opening of the interlayer insulating film while suppressing damages inflicted to the interlayer insulating layer made of, e.g., a low-k material (or porous material) which may be easily damaged.

Moreover, the demand for a low dielectric constant of the insulating layer (cap layer) 11B has recently grown. Hence, there has been suggested a structure in which the insulating layer 11B is made of a material containing Si and carbon as constituent elements, e.g., SiC, SiCN or the like, instead of a conventionally used SiN.

The method for removing a metal fluoride by using formic acid can suppress damages inflicted to the material such as SiC, SiCN or the like which is easily affected by etching or damages compared to SiN.

Further, the use of formic acid in the fluoride removal process in accordance with the present invention makes it possible to obtain the effect of increasing the reactivity to the fluoride removal (fluoride removal speed), compared to the use of, e.g., acetic acid. Accordingly, the substrate temperature in the fluoride removal process can be decreased (e.g., about 250° C. or below). As a result, the damages inflicted to the devices can be further reduced.

For example, acetic acid is different from formic acid in that the acetic acid has a single functional group (carboxyl group) for the reaction (fluoride removal), whereas the formic acid substantially has two functional groups (carboxyl group and aldehyde group) for the reaction. Namely, formic acid has a structure in which double bonds of C and O(C═O) are shared by the carboxyl group and the aldehyde group. This affects the difference in the reactivity between the two acids.

In addition, formic acid has a high vapor pressure compared to acetic acid or water, and thus can be easily supplied in a vaporized state.

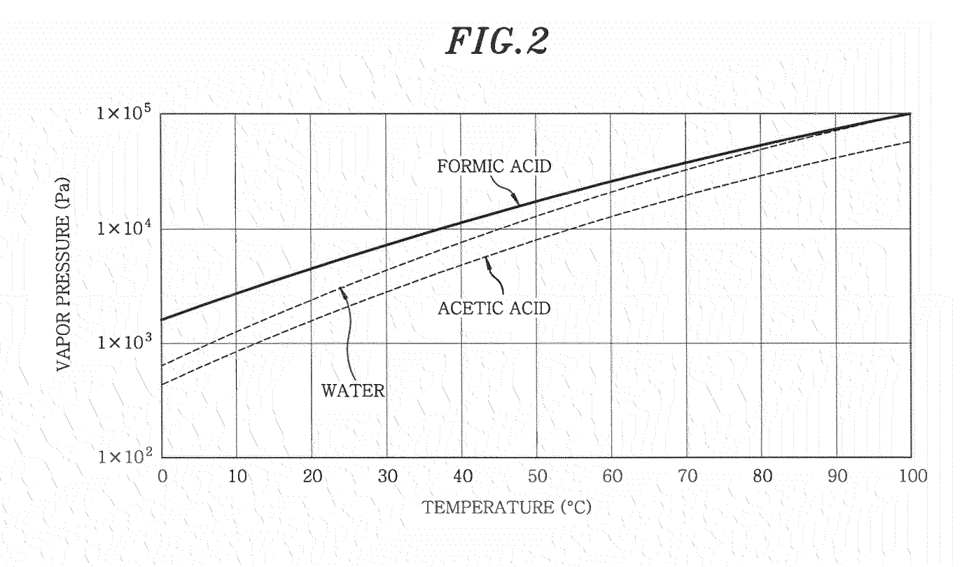

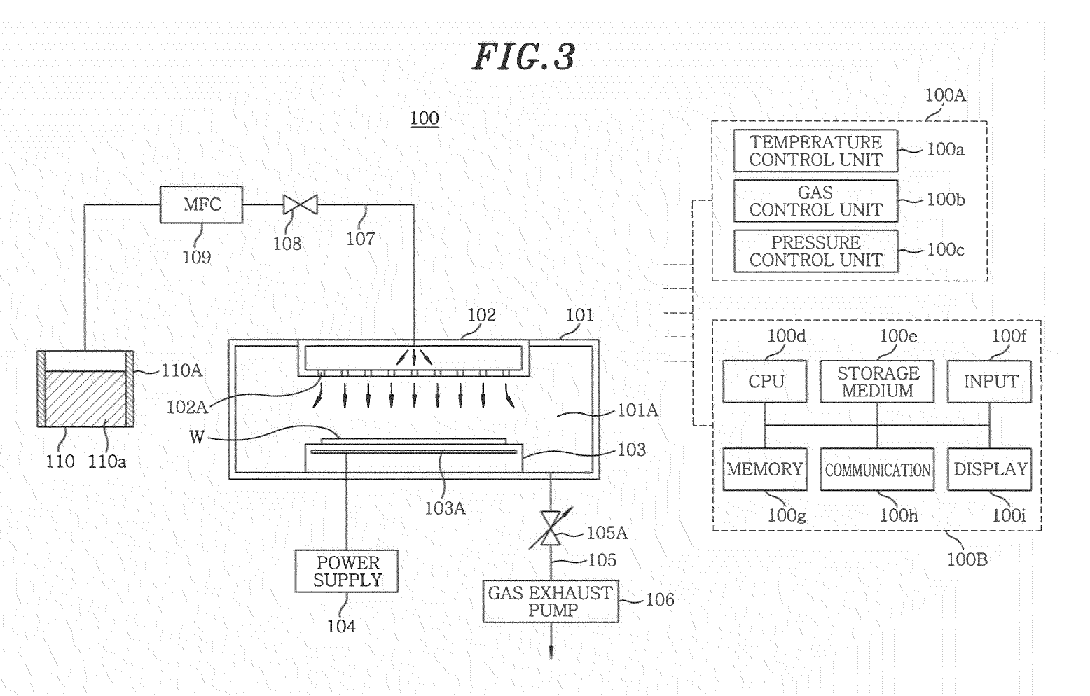

FIG. 2 illustrates vapor pressure curves of formic acid, acetic acid and water (see, “The properties of Gases and Liquids”, 5^{th} Edition). Referring to FIG. 2, it can be seen that the vapor pressure of formic acid is high in a wide temperature range compared to that of water or acetic acid. Consequently, formic acid can be easily and stably supplied in a vaporized state.

Moreover, formic acid hardly remains on the surface of the metal (Cu) after the fluoride removal process due to its high vapor pressure. Thus, the processing time (time required for removal of residues) can be shortened, and the process can be efficiently performed.

Further, it is considered that any one of the following reactions occurs when a metal (e.g., Cu) fluoride is removed by formic acid.

2CuF₂+HCOOH→2CuF+2HF+CO₂

2CuF+HCOOH→2Cu+2HF+CO₂

CuF₂+HCOOH→Cu+2HF+CO₂

CuF+HCOOH→Cu(HCOO)+HF

CuF₂+2HCOOH→Cu(HCOO)₂+2HF

2CuF₂+3HCOOH→2Cu(HCOO)+4HF+CO₂

Hereinafter, a specific exemplary configuration of the substrate processing apparatus for performing the fluoride removal process will be described with reference to drawings.

### First Embodiment

FIG. 3 schematically shows an exemplary configuration of a substrate processing apparatus in accordance with a first embodiment of the present invention. Referring to FIG. 3, a substrate processing apparatus 100 in accordance with this embodiment includes a processing chamber 101 which defines a processing space 101A therein. A supporting table 103 for supporting a substrate W to be processed is provided in the processing space 101A. A heater 103A for heating the substrate W is embedded in the supporting table 103. The heater 103A is connected with a power supply 104, and thus can heat the substrate W to a desired temperature.

Further, the processing space 101A is vacuum-evacuated through a gas exhaust line 105 connected with the processing chamber 101, and is maintained at a depressurized state. The gas exhaust line 105 is connected to a gas exhaust pump 106 via a pressure control valve 105A, so that the processing space 101A can be set to a depressurized state of a desired pressure.

Moreover, a gas supply unit 102 having, e.g., a shower head structure for supplying a processing gas into the processing chamber 101 is provided to face the supporting table 103 in the processing chamber 101. The gas supply unit 102 is connected to a gas supply line 107 for supplying a processing gas containing formic acid.

The gas supply line 107 is provided with a valve 108, a mass flow controller (MFC) 109, and is connected to a source supply unit 110 containing a source 110a of formic acid. The source supply unit 110 is provided with a heater 110A, and the source 110a is vaporized when heated by the heater 110A. The vaporized source is then supplied to the gas supply unit 102 via the gas supply line 107. Further, when the gas supply line 107 is heated to a temperature higher than a vaporization temperature of the source, the condensation of the gas in the gas supply line 107 is prevented, which is preferable.

The processing gas (vaporized source 101a) supplied to the gas supply unit 102 is introduced into the processing space 101A through a plurality of gas holes 102A formed at the gas supply unit 102. The processing gas introduced into the processing space 101A reaches the substrate W heated to a predetermined temperature by the heater 103A, and the fluoride is removed from, e.g., Cu wiring formed on the corresponding substrate W.

When the source 110a is vaporized or when the vaporized source (processing gas) 110a is supplied to the processing space 101A, the processing gas may be supplied to the processing space 101A together with a carrier gas, e.g., Ar, N₂, He or the like.

As for the carrier gas, a rare gas (e.g., Ne, Kr, Xe or the like) other than Ar or He can be used as long as it is chemically nonreactive. Further, the rare gas can be recycled and used by separating the rare gas from the used gas (exhausted gas) with the use of a rare gas separating and producing device.

Further, it is possible to add, to the processing gas, another gas which does not chemically affect a substance to be processed or has reducibility. The gas having reducibility includes, e.g., H₂, NH₃ or the like.

Substrate processing operations of the substrate processing apparatus 100 are controlled by a controller 100A, and the controller 100A is controlled by a program stored in a computer 100B. Moreover, wirings are not shown in the drawing.

The controller 100A includes a temperature control unit 100a, a gas control unit 100b and a pressure control unit 100c. The temperature control unit 100a controls the power supply 104 to control the temperature of the supporting table 103 and the temperature of the substrate W heated by the supporting table 103.

The gas control unit 100b controls the opening/closing of the valve 108 and the flow rate of the MFC 109 to control the state of the processing gas supplied to the processing space 101A. Further, the pressure control unit 100c controls the gas exhaust pump 106 and the opening degree of the pressure control valve 105A so that the processing space 101A can be maintained at a predetermined pressure.

Further, the controller 100A is controlled by the computer 100B, and the substrate processing apparatus 100 is operated by the computer 100B. The computer 100B includes a CPU 100d, a storage medium 100e, an input unit 100f, a memory 100g, a communication unit 100h and a display unit 100i. For example, a program related to the substrate processing method is recorded in the storage medium 100e, and the substrate processing is performed based on the corresponding program. Further, the corresponding program may be input by the communication unit 100h or by the input unit 100f.

Hereinafter, an example of the substrate processing conducted by using the substrate processing apparatus 100 and the results thereof will be explained in detail.

First of all, for preparation of the substrate processing, formic acid serving as the source 110a was filled in the source supply unit 110. Further, the source 110a was heated to a temperature of 298 to 333K (25 to 60° C.) by using the heater 110A provided around the source supply unit 110 to achieve a sufficient vapor pressure of the source. In this embodiment, the temperature of the source 110a was set to 298K (25° C.). In this state, it was possible to obtain the vapor pressure of about 6 kPa and ensure the sufficient gas flow rate.

The substrate processing to be described below was performed based on the above-described program. First, the substrate W having at least a part which is a metal (layer) to be processed was mounted on the supporting table 103, and the heater 103A was controlled by using the temperature control unit 100b so that the substrate W was heated to a temperature of 373 to 523K (100 to 250° C.).

Next, the processing gas was uniformly supplied from the gas supply unit 102 onto the substrate W by opening the valve 108 after three minutes from when the substrate W is mounted on the supporting table 103 by considering the heat transfer from the supporting table 103 to the substrate W.

Here, the MFC 109 was controlled by using the gas control unit 100b, and formic acid in a gaseous state was supplied into the processing chamber at a flow rate of 10 to 500 sccm. Further, the pressure control valve 105A was controlled by using the pressure control unit 100c so that the pressure of the processing space 101A was controlled to 10 to 2000 Pa. In this embodiment, the flow rate of the formic acid was set to 100 sccm; the pressure of the processing space 101A was set to 100 Pa; and the substrate temperature was set to 250° C. The treatment was performed on the substrate W held on the supporting table 103 for five minutes under the conditions of the controlled processing pressure and the controlled gas supply rate. Thereafter, the valve 108 was closed, and the processing gas remaining in the processing space 101A was evacuated by using the gas exhaust pump 106. Accordingly, the treatment was completed, and the substrate W was unloaded.

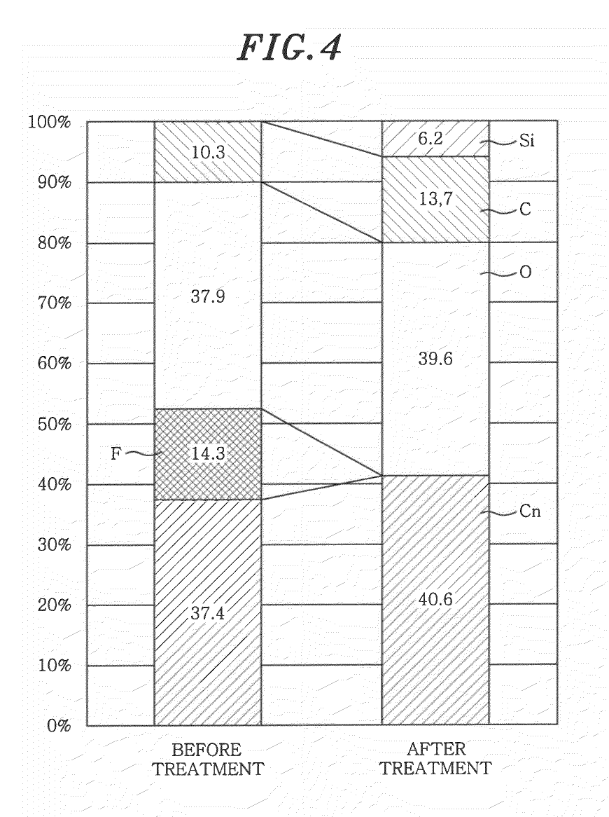

FIG. 4 shows the results of analysis of the Cu surface on the substrate by XPS (X-ray photoelectron spectroscopy) before and after the above-described treatment. Further, before the above-described treatment, a Cu fluoride layer was formed on the Cu surface by performing a process for exposing Cu on the substrate to a CF-based gas. Further, the process of exposure to the CF-based gas was performed inside a substrate processing chamber in which a high frequency power (RF power) was applicable to an upper and a lower electrode. In the above treatment, a pressure in the substrate processing chamber was set to 6 Pa; flow rates of CF₄ and N₂ supplied to the substrate processing chamber were set to 90 and 30 sccm, respectively; a gap between the upper electrode and the lower electrode was set to 60 mm; an RF power applied to the upper electrode was controlled to 400 W; an RF power applied to the lower electrode was set to 100 W; and processing time was set to 60 seconds.

Referring to FIG. 4, it is seen that fluorine that had been detected before the treatment was not detected (at least smaller than or equal to 1 atomic percent corresponding to a lowest detection limit) after the fluoride removal process using formic acid. Therefore, it was found that the Cu fluoride layer was removed by the above-described treatment.

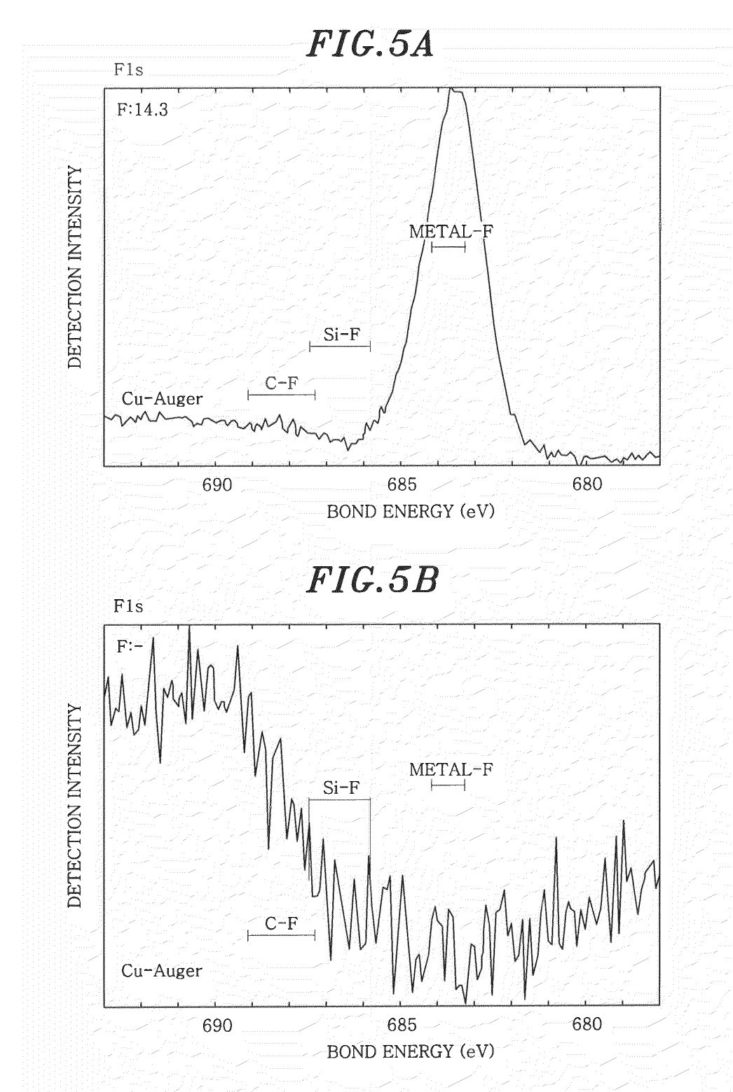

FIG. 5A illustrates a F1s XPS spectrum obtained before the formic acid treatment, and FIG. 5B depicts a F1s XPS spectrum obtained after the formic acid treatment. The units of vertical axes in FIGS. 5A and 5B are arbitrary and different from each other. Moreover, FIGS. 5A and 5B show positions of bond energy corresponding to C—F bond, that corresponding to Si—F bond, and that corresponding to metal-F bond. Referring to FIGS. 5A and 5B, there is illustrated that a metal-F bond peak decreases considerably after the formic acid treatment, which indicates the removal of F bonded to a metal.

### Second Embodiment

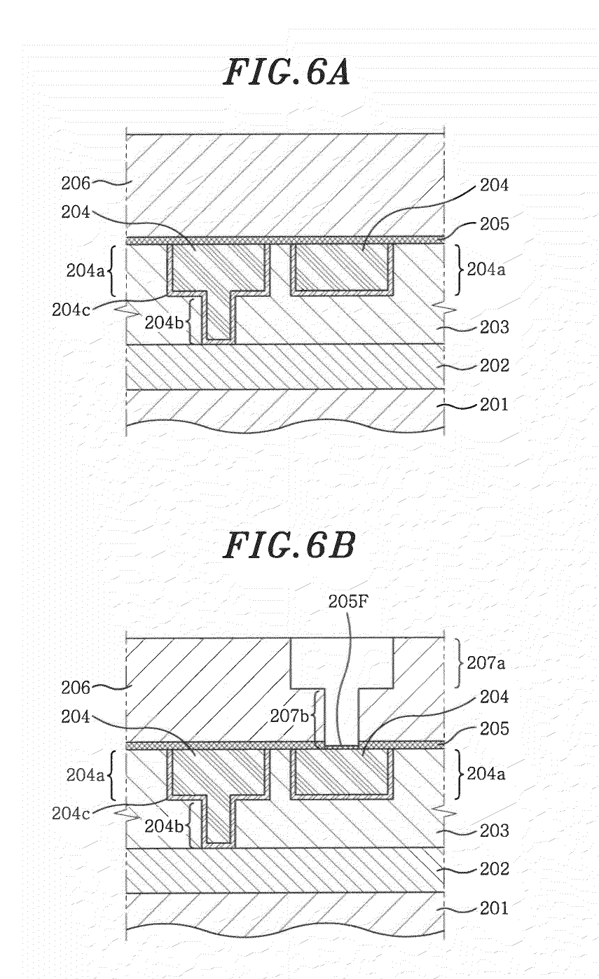

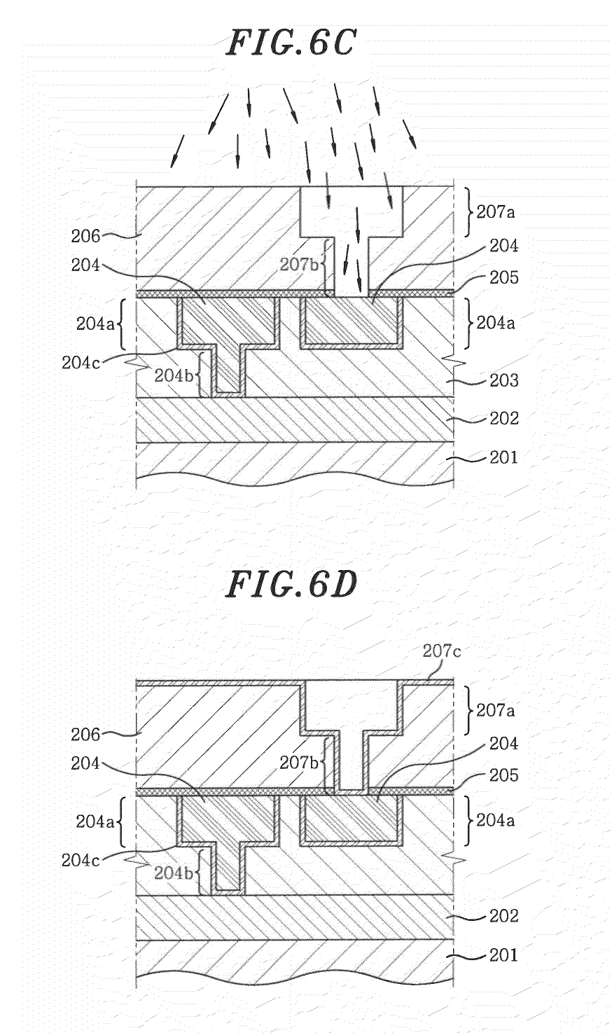

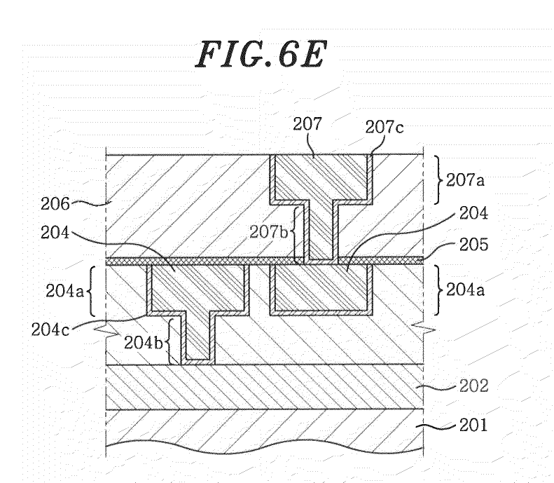

Hereinafter, a specific example of a method for manufacturing a semiconductor device by using the substrate processing apparatus described in the first embodiment will be explained with reference to FIGS. 6A to 6E.

First of all, in the semiconductor device in a process shown in FIG. 6A, an insulating film (interlayer insulating layer) 201, e.g., a silicon oxide film, is formed so as to cover elements (not shown) such as a MOS transistor and the like formed on a semiconductor substrate (substrate W to be processed) made of silicon. Further, there are formed a wiring layer (not shown) which is made of, e.g., tungsten W, and electrically connected to the corresponding elements and a wiring layer 202 which is made of, e.g., Cu, and connected thereto.

A first insulating layer (interlayer insulating film) 203 is formed on the silicon oxide film 201 so as to cover the wiring layer 202. A groove portion 204a and a hole portion 204b are formed in the first insulating layer 203. A wiring portion 204 made of Cu and having trench wiring and via plug is formed in the groove portion 204a and the hole portion 204b, and is electrically connected with the wiring layer 202.

Moreover, a Cu diffusion barrier film 204c is formed between the first insulating film 203 and the wiring portion 204. The Cu diffusion barrier film 204c prevents Cu diffusion from the wiring portion 204 into the first insulating layer 203. In addition, an insulating film (cap layer of Cu) 205 and a second insulating layer (an interlayer insulating film) 206 are stacked so as to cover the wiring portion 204 and the first insulating layer 203.

Hereinafter, the method for manufacturing a semiconductor device by forming Cu wiring by applying the aforementioned fluoride removal process to the second insulating layer 206 will be described. The wiring portion 204 may also be formed in the manner to be described below.

In a process shown in FIG. 6B, an opening including a groove portion 207a and a hole portion 207b (the hole portion 207b passing through the insulating layer 205) is formed in the second insulating layer 206 by a plasma etching method using a fluorocarbon-based etching gas containing, e.g., fluorine, as a constituent element (etching (opening forming) process).

Further, an ashing process for removing, by ashing, a resist pattern (not shown) used in the etching process may be carried out after the etching process.

Here, a part of the wiring portion 204 made of Cu is exposed through an opening formed in the second insulating layer 206. A top surface of the exposed wiring portion 204 is fluoridized by fluorine contained in the etching gas for etching the insulating layer 206 (insulating layer 205), so that a Cu fluoride layer 205F is formed.

Next, in a process shown in FIG. 6C, the Cu fluoride layer 205F on the exposed wiring portion 204 is removed by using the substrate processing apparatus 100 described in the first embodiment. At this time, the Cu fluoride layer 205F is removed by supplying vaporized formic acid to the substrate and heating the substrate at the same time.

Further, the temperature of the substrate is preferably higher than or equal to 373K (100° C.) because the removal of the Cu fluoride layer 205F is not sufficiently facilitated at a low temperature. That is, the temperature of the substrate preferably ranges from 373 to 523K (100 to 250° C.).

Then, in a process of FIG. 6D, a Cu diffusion barrier film 207c is formed on the second insulating layer 206 including the inner wall surfaces of the groove portion 207a and the hole portion 207b and on the exposed surface of the wiring portion 204. The Cu diffusion barrier film 207c is formed of a high-melting point metal film or a nitride film thereof, or stacked films thereof. For example, the Cu diffusion barrier film 207c may be formed of a Ta/TaN film, a WN film or a TiN film by using a sputtering, CVD method or the like. Besides, the Cu diffusion barrier film may also be formed by using a so-called ALD method.

Next, in a process shown in FIG. 6E, a wiring portion 207 made of Cu is formed on the Cu diffusion barrier film 207c so as to be filled in the groove portion 207a and the hole portion 207b. In this case, a seed layer made of Cu is formed by a sputtering or CVD method and, then, the wiring portion 207 is formed by Cu electroplating. Further, after the wiring portion 207 is formed, the surface is planarized by chemical mechanical polishing (CMP), and surplus Cu is removed. The wiring portion 207 may also be formed by a CVD or an ALD method.

Further, a semiconductor device having a multilayer wiring structure can be fabricated by forming, upon completion of the above process, a (2+n)^{th} insulating layer (n being a natural number) on top of the second insulating layer 206 and then forming a wiring portion made of Cu in the insulating layer by using the above-described method.

Although the case where the Cu multilayer wiring structure is formed by using a dual damascene method has been described in the second embodiment, the above-described method can also be applied to a case where a Cu multilayer wiring structure is formed by using a single damascene method.

Further, although the Cu wiring has been used as metal wiring (metal layer) formed in the insulating layer in this embodiment, the present invention is not limited thereto. For example, the embodiment of the present invention may also be applied to metal electrode (metal layer) or metal wiring made of, e.g., Al, Ag, W, Co, Ni, Ru, Ti, Ta or the like, other than Cu.

For example, by applying the present invention, a fluoride layer of a source electrode or a drain electrode can be removed after plasma-etching the insulating layer covering the source electrode or the drain electrode of the MOS transistor by using a fluorocarbon-based gas. The source electrode or the drain electrode is made of, e.g., a silicide compound of Ni or Co. Thus, the present invention can be also applied to the case of removing a fluoride of Ni or Co.

In addition, by applying the present invention, a fluoride layer of a gate electrode can be removed after plasma-etching the insulating layer covering the gate electrode made of a metal, e.g., Al or the like, by using a fluorocarbon-based gas.

The above-described etching process and fluorine removal process may be performed successively by using, e.g., a cluster-type substrate processing apparatus. The use of the cluster-type substrate processing apparatus makes it possible to successively perform a Cu diffusion barrier film forming process and a process for forming a seed layer for Cu electroplating after the fluorine removal process. Hereinafter, an example of a configuration of the cluster-type substrate processing apparatus will be described.

### Third Embodiment

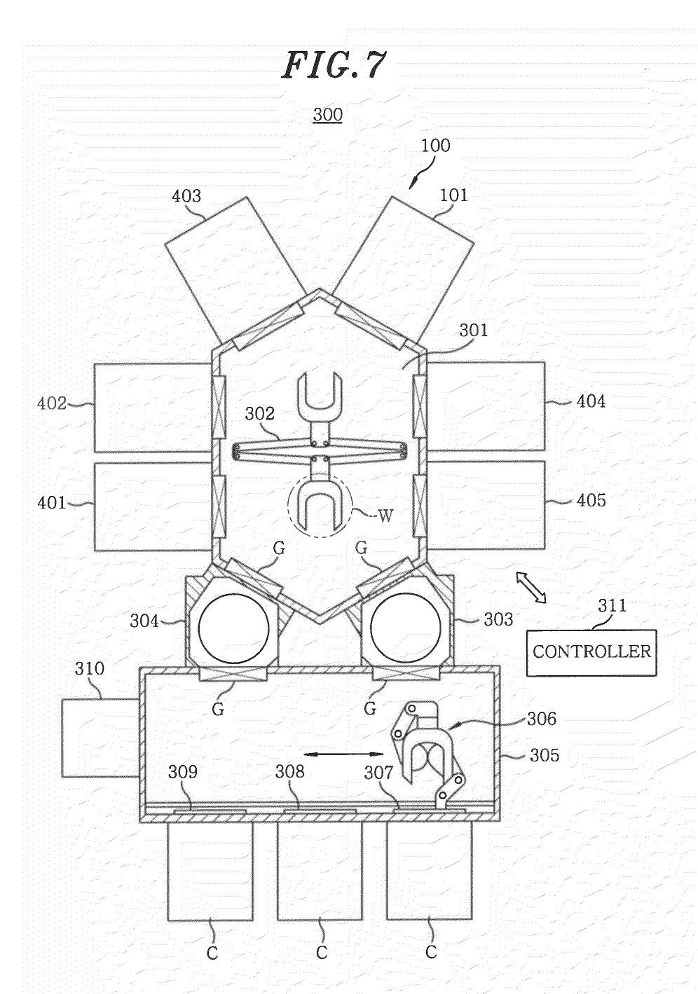

FIG. 7 is a plan view schematically showing a configuration of a cluster-type substrate processing apparatus 300 including the above-described substrate processing apparatus 100. Referring to FIG. 7, the substrate processing apparatus 300 shown in this drawing has a schematic structure in which a transfer chamber 301 having a predetermined depressurized state or nonreactive gas atmosphere is connected to processing chambers 401, 402, 403, 404 and 405 in addition to the substrate processing apparatus 100 (processing chamber 101).

Further, a transfer arm 302 which is rotatable, extensible and contractible is installed inside the transfer chamber 301, so that the substrate W can be transferred between the processing chambers by using the transfer arm 302.

Moreover, load-lock chambers 303 and 304 are connected to the transfer chamber 301, and are also connected to a substrate loading/unloading chamber 305 on the side opposite to the side at which they are connected to the transfer chamber 301. Further, the substrate loading/unloading chamber 305 is provided with ports 307, 308 and 309 for attachment of carriers C capable of accommodating therein substrates W to be processed. Besides, an alignment chamber 310 is provided at a side surface of the substrate loading/unloading chamber 305, and performs alignment of the substrate W.

In addition, a transfer arm 306 for loading/unloading the substrate W into/from the load-lock chambers 303 and 304 and the carriers C is installed in the substrate loading/unloading chamber 305. The transfer arm 306 has a multi-joint arm structure, and transfers the substrate W mounted thereon.

The processing chambers 101, 401, 402, 403, 404 and 405 and the load-lock chambers 303 and 304 are connected to the transfer chamber 301 via gate valves G. The processing chambers or the load-lock chambers communicate with the transfer chamber 301 by opening the gate valves G, and are blocked from the transfer chamber 301 by closing the gate valves G. Besides, the same gate valves G are also provided at connecting portions between the load-lock chambers 303 and 304 and the substrate loading/unloading chamber 305.

The operation in accordance with the transfer of the substrate W is controlled by a controller 311. The controller 311 is connected to the computer 100B described in FIG. 2 (connection wiring not being shown). The operation in accordance with the substrate processing of the substrate processing apparatus 300 (transfer of the substrate W) is performed by the program recorded in the storage medium 100e of the computer 100B. Further, the substrate processing in the processing chambers 401 to 405 is performed by the program recorded in the storage medium 100e of the computer 100B.

The substrate processing using the substrate processing apparatus 300 is performed as will be described hereinafter. First, a substrate W having a structure in which Cu wiring is covered with an insulating layer (corresponding to the state shown in FIG. 6A) is unloaded from the carrier C and then is loaded into the load-lock chamber 303 by using the transfer arm 306. Next, the substrate W is transferred by using the transfer arm 302 from the load-lock chamber 303 to the processing chamber 401 or 402 via the transfer chamber 301. In the processing chamber 401 or 402, the etching process described in FIG. 6B is carried out. As a consequence, an opening is formed in the insulating layer on the Cu wiring, and a part of the Cu wiring is exposed.

Next, the substrate W is transferred from the processing chamber 401 or 402 to the processing chamber 403 by using the transfer arm 302. In the processing chamber 403, the ashing is performed to remove a resist mask used for the etching.

Then, the substrate W is transferred from the processing chamber 403 to the processing chamber 101 by using the transfer arm 302. In the processing chamber 101, the process shown in FIG. 6C is performed, thereby removing a Cu fluoride formed on the Cu wiring surface.

Thereafter, the substrate W is transferred from the processing chamber 101 to the processing chamber 404 by using the transfer arm 302. In the processing chamber 404, the process illustrated in FIG. 6D is carried out, so that a Cu diffusion barrier film made of, e.g., Ta/TaN film, a WN film, a TiN film or the like, is formed on the insulating film and the Cu wiring by, e.g., a sputtering method, a CVD method or the like.

Next, the substrate W is transferred from the processing chamber 404 to the processing chamber 405 by using the transfer arm 302. In the processing chamber 405, a seed layer made of Cu is formed on the Cu diffusion barrier film by, e.g., a sputtering method or a CVD method.

The substrate W that has been subjected to the above-described processes is transferred to the load-lock chamber 304 by using the transfer arm 302, and then is transferred from the load-lock chamber 304 to a predetermined carrier C by using the transfer arm 306. By successively performing this series of processes on substrates W accommodated in the carrier C, a plurality of substrates can be processed successively.

In accordance with the substrate processing apparatus 300, it is possible to suppress oxidation of Cu wiring due to exposure of the substrate W to oxygen, deterioration of a low-k film due to exposure to moisture, adhesion of contaminants to the substrate W or the like. Thus, the substrate processing can be cleanly performed.

The configuration of the cluster-type substrate processing apparatus is not limited to the above-described one, and the configuration or the number of processing chambers may be variously modified and changed. Further, for example, the formic acid treatment may be performed after the aforementioned etching process and, then, the ashing process may be performed.

While the invention has been shown and described with respect to the embodiments, various changes and modification may be made without departing from the scope of the invention as defined in the following claims.

### INDUSTRIAL APPLICABILITY

In accordance with the present invention, it is possible to provide a semiconductor device having high reliability be reducing fluorine remaining in a metal forming the semiconductor device.

This application claims priority to Japanese Patent Application No. 2007-059112, filed on Mar. 8, 2007, the entire contents of which are hereby incorporated by reference.

What is claimed is:

1. A method for manufacturing a semiconductor device comprising:
a fluoride removal step for removing a metal fluoride produced on a metal forming an electrode or wiring of a semiconductor device formed on a substrate to be processed,
wherein in the fluoride removal step, the metal fluoride is removed by supplying a formic acid in a gaseous state to the substrate.

2. The method of claim 1, wherein the metal is Cu.

3. The method of claim 1, wherein in the fluoride removal step, a metal fluoride produced on the metal exposed through an opening of an insulating layer formed on the metal is removed.

4. The method of claim 3, further comprising an opening forming step for forming the opening, wherein the metal fluoride is produced during the opening forming step.

5. The method of claim 4, wherein the opening forming step and the metal fluoride removal step are carried out successively in a depressurized state.

6. The method of claim 3, wherein the insulating layer contains silicon and carbon as constituent elements.

7. The method of claim 3, wherein the insulating layer contains silicon and carbon as constituent elements, and at least a part of the insulating layer is porous.

8. A storage medium storing a program for executing, on a computer, a substrate processing method in a substrate processing apparatus including a processing chamber for processing a substrate to be processed,
wherein the substrate processing method includes a fluoride removal step for removing a fluoride of a metal by supplying formic acid in a gaseous state to the processing chamber.

9. The storage medium of claim 8, wherein the metal is Cu.

10. The storage medium of claim 8, wherein in the fluoride removal step, a metal fluoride produced on the metal exposed through an opening of an insulating layer formed on the metal is removed.

11. The storage medium of claim 10, wherein the substrate processing method further includes an opening forming step for forming the opening, wherein the metal fluoride is produced during the opening forming step.

12. The storage medium of claim 11, wherein the opening forming step and the metal fluoride removal step are carried out successively in a depressurized state.

13. The storage medium of claim 10, wherein the insulating layer contains silicon and carbon as constituent elements.

14. The storage medium of claim 10, wherein the insulating layer contains silicon and carbon as constituent elements, and at least a part of the insulating layer is porous.
